(19) United States
(12) Patent Application Publication
(10) Pub. No.: US 2019/0357386 A1
(43) Pub. Date: Nov. 21, 2019

(54) VASCULAR POLYMERIC ASSEMBLY

(71) Applicant: GM GLOBAL TECHNOLOGY OPERATIONS LLC, DETROIT, MI (US)

(72) Inventors: Anthony M. Coppola, Rochester Hills, MI (US); Alireza Fatemi, Rochester Hills, MI (US); Rashmi Prasad, Troy, MI (US)

(21) Appl. No.: 15/981,190

(22) Filed: May 16, 2018

(51) Int. Cl. H05K 7/20; B29C 45/14; B29C 45/00; F28F 3/12; F28F 21/06

(52) U.S. Cl. CPC H05K 7/20263; B29C 45/14; B29C 45/0055; B29L 2031/18; F28F 21/065; B29C 2045/0058; F28F 3/12

(57) ABSTRACT

A vascular polymeric assembly is provided which includes a heat source, a polymeric substrate configured to enclose and protect at least a portion of the heat source; and a channel defined in the polymeric substrate configured to transfer a heat flow away from the heat source via a channel coolant flow.

### TECHNICAL FIELD

The present disclosure generally relates to the cooling and protection of a heat source. In particular, the present invention relates to an assembly which provide thermal management benefits as well as protection to powered components which include, but are not limited to, an electronics board, a motor component such as a stator, or a portion of a motor component.

### BACKGROUND

As is known, many powered devices produce heat. This heat should be removed from the devices in order to maintain device junction temperatures within desirable limits: failure to remove the heat thus produced results in increased device temperatures, potentially leading to thermal runaway conditions. Several trends in the electronics industry have combined to increase the importance of thermal management, including heat removal for electronic devices. In particular, the need for faster and more densely packed circuits has had a direct impact on the importance of thermal management. First, power dissipation, and therefore heat production, increases as the device operating frequencies increase. Second, increased operating frequencies may be possible at lower device junction temperatures. Finally, as more and more devices are packed onto a single chip, power density (Watts/cm²) increases, resulting in the need to remove more power from a given size chip or module. These trends have combined to create applications where it is no longer desirable to remove the heat from modern devices solely by traditional air cooling methods, such as by using traditional air-cooled heat sinks.

As is also known, electronic devices are more effectively cooled through the use of a cooling fluid, such as chilled water or a refrigerant. For example, electronic devices may be cooled through the use of a cold plate in thermal contact with the electronic devices. Chilled water (or other cooling fluid) is circulated through the cold plate, where heat is transferred from the electronic devices to the cooling fluid. The cooling fluid then circulates through an external heat exchanger or chiller, where the accumulated heat is transferred from the cooling fluid. Fluid flow paths are provided connecting the cold plates to each other and to the external heat exchanger or chiller. These fluid flow paths are constructed of conduits such as, for example, copper tubing, which are typically joined to cold plates by one or more mechanical connections.

A cold plate fluid distribution assembly constructed using known methods and materials, however, may be rather bulky in size and heavy due to the components generally implemented in a cold plate assembly. Manufacturing and assembly tolerances in electronic devices, boards, cold plates, etc., may result in variations in component dimensions and alignment, requiring some degree of flexibility in the multi-cold plate fluid distribution assembly in order to simultaneously maintain good thermal contact with all associated electronic devices. For example, manufacturing and process tolerances may cause similar types of modules, such as processor modules, to vary in height by several millimeters.

As shown in FIG. 1A, an isometric view of a traditional cooling plate for a heat source is provided wherein the heat source may be a vehicle's electronics module. FIG. 1B provides an isometric view of the cooling plate in FIG. 1A with the top cover removed and the cooling channel exposed. FIG. 1C is an isometric view of the electronics module cavity in the cooling plate of FIG. 1A. FIG. 2 is a schematic cross-sectional view of a traditional cooling plate and an electronics module wherein the coolant flow is shown such that the coolant flow transfers heat away from only one side of the electronics module.

Alternatively, known materials and methods may be used to create a multi-cold plate fluid distribution assembly having sufficient flexibility but which lacks the reliability improvements associated with a reduced number of mechanical conduit connections. For example, a number of metal cold plates may be plumbed together using flexible tubing, such as plastic tubing. Since plastic tubing cannot be soldered, brazed, or otherwise reliably and permanently joined to a metal cold plate, a mechanical connection is required between the plastic tubing and each inlet and outlet of each cold plate. As previously noted, increasing the number of mechanical conduit connections increases the potential points of failure in the cooling distribution assembly. Thus, known materials and methods may provide a multi-cold plate fluid distribution assembly that is sufficiently flexible to maintain good thermal contact with associated electronic devices in the presence of normal manufacturing and assembly process variations, however such flexibility is obtained at the expense of the reliability improvement that served as motivation for creating the multi-cold plate fluid distribution assembly.

Accordingly, it is desirable to provide an assembly which can house and protect a heat source such as an electronics board in a compact and lightweight manner while also managing thermal energy generated by the heat source. In addition, it is desirable to reduce the number of components which are generally implemented in such assemblies. Further, other desirable features and characteristics of the present invention will become apparent from the subsequent detailed description and the appended claims, taken in conjunction with the accompanying drawings and the foregoing technical field and background.

### SUMMARY

The present disclosure provides a vascular polymeric assembly wherein the assembly includes a heat source and a housing for the heat source. The heat source may, but not necessarily be, a high-powered electronics module which is prone to generating heat such as, but not limited to, an IGBT or MOSFET module for electric vehicles. The housing is configured to transfer heat away from the heat source while also protecting the heat source. Moreover, the polymeric assembly of the present disclosure has reduced weight and reduced components relative to traditional coolant plates used for such high-powered electronics modules/boards.

In a first embodiment, the vascular polymeric assembly may include a heat source, a polymeric substrate, and a channel(s) defined in the polymeric substrate. The channel or channels are configured to transfer heat away from the heat source via a coolant flow moving through the channel(s). The polymeric substrate of the present disclosure may be configured to distribute heat, enclose, and protect at least a portion of the heat source. As one option, a channel defined in the polymeric substrate may be in fluid communication with heat source. As yet another optional enhancement to this, the channel which is in fluid communication with the heat source may further define an increased cross-section in the region where the channel intersects with the heat source. The polymeric substrate may be formed from a rigid polymeric material when the polymeric substrate completely encloses and protects the heat source. In this embodiment using a rigid polymeric material for the polymeric substrate (as well as other embodiments which implement a flexible polymeric material for the polymeric substrate), the vascular polymeric assembly may further include an internal support structure configured to support the heat source. The internal support structure may be enclosed and protected with the heat source within the polymeric substrate.

In this first embodiment, it is understood that the channel(s), defined in the polymeric substrate, may, but not necessarily, be provided in both an upper region and a lower region of the polymeric substrate. As yet another option, an upper heat spreader may be disposed adjacent to channel(s) defined in an upper region of the polymeric substrate while a lower heat spreader may also be disposed adjacent to the channel(s) defined in a lower region of the polymeric substrate.

In a second embodiment, the vascular polymeric assembly may include a heat source, a polymeric substrate, and a channel(s) defined in the polymeric substrate in addition to a plate and a structural case which is disposed on the plate. The structural case may or may not be made from a polymeric material. The structural case is configured to support the heat source and polymeric substrate. The plate may further define a plate coolant channel. The plate coolant channel, the plate and structural case are configured to distribute heat away from a lower side of the heat source via a plate coolant flow which moves through the plate coolant channel, while the channel(s) in the polymeric substrate are configured to transfer heat away from an upper side of the heat source via a channel coolant flow which moves through the channel(s). As one option, the channel(s) defined in the polymeric substrate may be in fluid communication with heat source. As yet another optional enhancement to this, the channel(s) which is/are in fluid communication with the heat source may further define an increased cross-section in the region where the channel(s) intersects with the heat source. In this embodiment which implements a plate and a structural case, the polymeric substrate may be formed by a flexible polymer. The flexible polymer defines a service temperature which is well above a glass transition temperature. The flexible polymer material used in the polymeric substrate may, but not necessarily, be one of a rubber, a silicone, or an elastomer.

In a third embodiment of the present disclosure, a structural polymeric case may be used instead of a structural case and the plate. In this embodiment, the vascular polymeric assembly includes a heat source, a polymeric substrate, and a channel(s) defined in the polymeric substrate and a structural polymeric case. The structural polymeric case similarly supports the heat source and the polymeric substrate as previously described. However, the structural polymeric case obviates the need for a plate having a plate coolant channel given that the structural polymeric case also defines a coolant channel(s) which configured to transfer heat away from a lower side of the heat source via a lower coolant flow which travels through the lower coolant channel(s). The structural polymeric case may be formed from a structural polymer which is in a glassy state such that the structural polymer's service temperature is below a glass transition temperature. The structural polymer material used for the structural polymeric case may, but not necessarily, be one of an epoxy, a polyurethane, a polyimide, a polypropylene, a nylon, a bismaleimide, a benzoxazine, a phenolic, a polyester, a polyvinylchloride, a melamine, a cyanate ester, a silicone, a vinyl ester, a thermoplastic olefin, a polycarbonate, a polyether sulfone, a polystyrene, or a polytetrafluoroethylene.

The present disclosure also provides a method for manufacturing a vascular polymeric assembly which includes the steps of: (1) providing a heat source; (2) wrapping the heat source with a sacrificial material; (3) placing the heat source wrapped in the sacrificial material in a mold; (4) filling the mold with a polymeric material wherein the polymeric material encloses at least a portion of the heat source and the sacrificial material; (5) curing the polymeric material in the mold thereby creating an encased product; (6) removing the encased product from the mold; and (7) removing the sacrificial material disposed within the mold and defining a channel(s). The method may optionally further include one or more of the following steps: the step of providing a coolant flow through the channel(s); and the step of disposing the heat source in a structural case and placing the heat source and the structural case together in the mold. The heat source implemented in the aforementioned manufacturing method may, but not necessarily be, an electronics module.

It is understood that the step of filling the mold with the polymeric material may, but not necessarily be performed by a dual shot injection molding process wherein a structural polymer is provided in at least a lower region of the mold below the heat source and a flexible polymer is provided in at least an upper region of the mold above the heat source. Alternatively, the step of filling the mold with the polymeric material may, but not necessarily, be performed by a single injection molding process wherein the mold is filled with one structural polymer.

With respect to the step of wrapping the heat source in the sacrificial material, it is understood that this step may be performed in a variety of ways. One example method of wrapping the heat source involves wrapping only an upper side of the heat source with the sacrificial material. Another, non-limiting example method of wrapping the heat source involves wrapping the heat source in a sacrificial material includes wherein both an upper side and a lower side of the heat source are wrapped.

The present disclosure and its particular features and advantages will become more apparent from the following detailed description considered with reference to the accompanying drawings.

### BRIEF DESCRIPTION OF THE DRAWINGS

These and other features and advantages of the present disclosure will be apparent from the following detailed description, best mode, claims, and accompanying drawings in which:

FIG. 1A provides an isometric view of a traditional cooling plate for a heat source such as a vehicle's electronics module.

FIG. 1B provides an isometric view of the cooling plate in FIG. 1A with the top cover removed and the cooling channel exposed.

FIG. 1C is an isometric view of the electronics module cavity in the cooling plate of FIG. 1A.

FIG. 2 is a schematic cross-sectional view of a traditional cooling plate and an electronics module wherein a coolant flow transfers heat away from one side of the electronics module.

FIG. 3 illustrates a first embodiment of the present disclosure wherein polymeric substrate completely encloses and protects the heat source.

FIG. 4A illustrates the first embodiment of the present disclosure wherein a heat spreader is disposed between the heat source and the channel(s) in each of the upper region and the lower region of the polymeric substrate.

FIG. 4B illustrates an example, non-limiting attachment of the heat spreader to the sacrificial material.

FIG. 5 is a second embodiment of the present disclosure wherein channels in the polymeric substrate transfer heat away from an upper side of a heat source.

FIG. 6 illustrates the second embodiment of the present disclosure wherein a second polymeric substrate transfers heat away from a lower side of the heat source via the channel(s) and a lower coolant flow.

FIG. 7A illustrates an example, non-limiting schematic side view of the heat source being in fluid communication with the channel(s).

FIG. 7B illustrates an example, non-limiting schematic top/bottom view of the heat source and the least one channel of FIG. 7A.

FIG. 8A illustrates an example, non-limiting schematic side view of the heat source being in fluid communication with the channel in the channel(s) wherein the channel has an increased cross-section in the region where the channel intersects with the heat source.

FIG. 8B illustrates an example, non-limiting schematic top/bottom view of the heat source and the least one channel of FIG. 8A.

FIG. 9A illustrates an example, non-limiting schematic top/bottom view of a channel(s) defined above/below a heat source enclosed in a polymeric substrate.

FIG. 9B illustrates an example, non-limiting schematic side view of a channel(s) defined adjacent to one of a first and second side of heat source enclosed in a polymeric substrate.

FIG. 10A illustrates an example, non-limiting schematic side view of the second embodiment housing which further includes an internal support structure.

FIG. 10B illustrates a top view of the internal support structure of FIG. 10A.

FIG. 11 illustrates an example non-limiting method of manufacturing a vascular polymeric assembly according to the present disclosure.

FIG. 12 illustrates a cross-sectional view of an example, non-limiting sacrificial material.

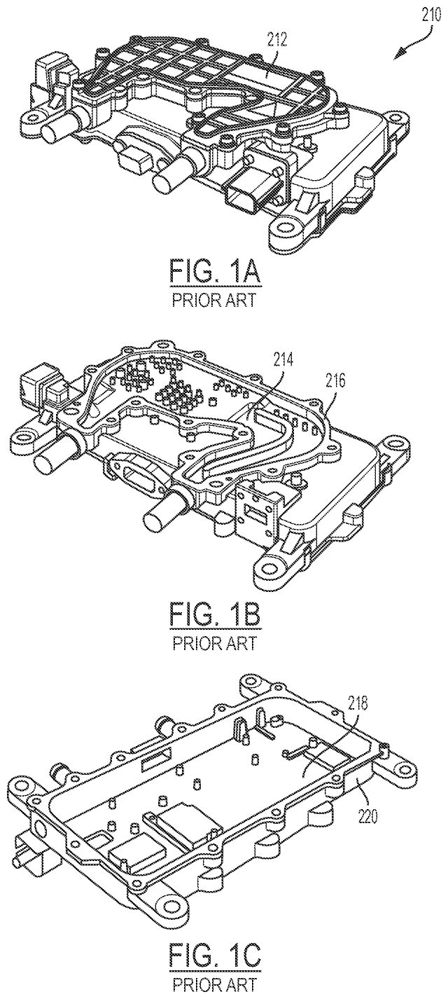

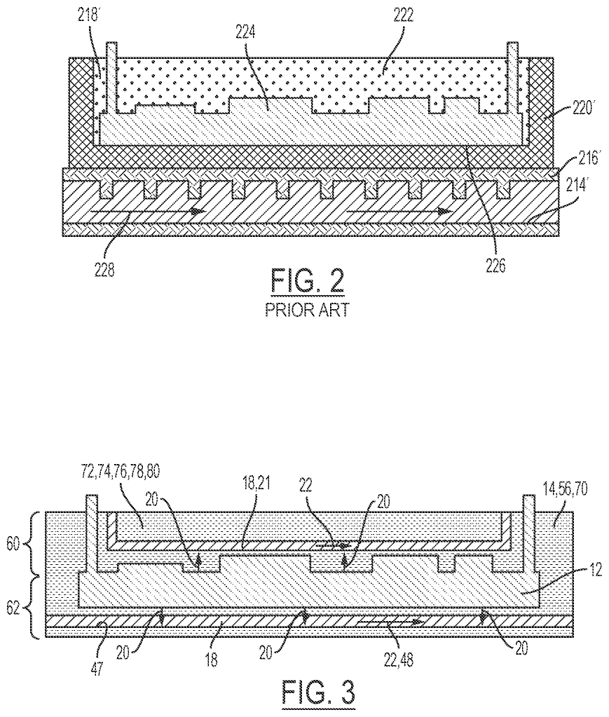

Like reference numerals refer to like parts throughout the description of several views of the drawings.

### DETAILED DESCRIPTION

Reference will now be made in detail to presently preferred compositions, embodiments and methods of the present disclosure, which constitute the best modes of practicing the present disclosure presently known to the inventors. The figures are not necessarily to scale. However, it is to be understood that the disclosed embodiments are merely exemplary of the present disclosure that may be embodied in various and alternative forms. Therefore, specific details disclosed herein are not to be interpreted as limiting, but merely as a representative basis for any aspect of the present disclosure and/or as a representative basis for teaching one skilled in the art to variously employ the present disclosure.

Except in the examples, or where otherwise expressly indicated, all numerical quantities in this description indicating amounts of material or conditions of reaction and/or use are to be understood as modified by the word “about” in describing the broadest scope of the present disclosure. Practice within the numerical limits stated is generally preferred. Also, unless expressly stated to the contrary: percent, “parts of,” and ratio values are by weight; the description of a group or class of materials as suitable or preferred for a given purpose in connection with the present disclosure implies that mixtures of any two or more of the members of the group or class are equally suitable or preferred; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It is also to be understood that this present disclosure is not limited to the specific embodiments and methods described below, as specific components and/or conditions may, of course, vary. Furthermore, the terminology used herein is used only for the purpose of describing particular embodiments of the present disclosure and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

The term “comprising” is synonymous with “including,” “having,” “containing,” or “characterized by.” These terms are inclusive and open-ended and do not exclude additional, un-recited elements or method steps.

The phrase “consisting of” excludes any element, step, or ingredient not specified in the claim. When this phrase appears in a clause of the lifter body 14 of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

The terms “comprising”, “consisting of”, and “consisting essentially of” can be alternatively used. Where one of these three terms is used, the presently disclosed and claimed subject matter can include the use of either of the other two terms.

The terms “upper” and “lower” may be used with respect to regions of a single component and are intended to broadly indicate regions relative to each other wherein the “upper” region and “lower” region together form a single component. The terms should not be construed to solely refer to vertical distance/height.

Throughout this application, where publications are referenced, the disclosures of these publications in their entireties are hereby incorporated by reference into this application to more fully describe the state of the art to which this present disclosure pertains.

The following detailed description is merely exemplary in nature and is not intended to limit the present disclosure or the application and uses of the present disclosure. Furthermore, there is no intention to be bound by any theory presented in the preceding background or the following detailed description.

The following detailed description is merely exemplary in nature and is not intended to limit the invention or the application and uses of the invention. Furthermore, there is no intention to be bound by any expressed or implied theory presented in the preceding technical field, background, brief summary, or the following detailed description.

The present disclosure provides a vascular polymeric assembly 10 wherein the assembly includes a heat source 12 and a housing for the heat source 12. The housing is configured to transfer heat 20 away from the heat source 12 while also protecting the heat source 12. Moreover, the polymeric assembly of the present disclosure has reduced weight and reduced components relative to traditional coolant plates used for heat sources such as high-powered electronics module/boards 102 or the like. However, it is understood that with respect to all embodiments of the present disclosure, the heat source 12 should be construed to be any powered component which generates heat such as, but not limited to, a high-powered electronics module, a motor component (such as but not limited to a stator), a portion of a motor component (such as but not limited to ends of stator windings), or at least a portion of an internal combustion engine (such as but not limited to a cylinder head). In the non-limiting example where the heat source 12 is provided in the form of a high-powered electronics module 12 which is prone to generating heat 20 such module may be an IGBT module or a MOSFET for electric vehicles.

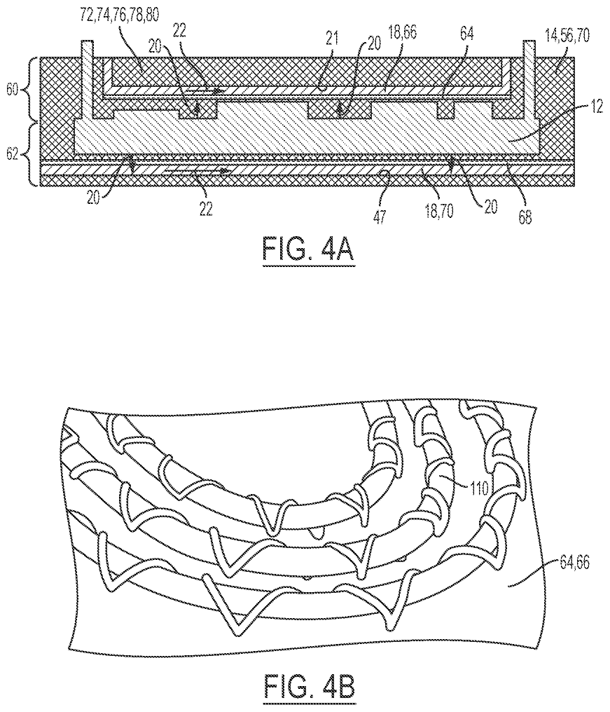

With reference to FIGS. 3, and 4A-4B, the first embodiment of the present disclosure is shown wherein a vascular polymeric assembly 10 may include a heat source 12, a polymeric substrate 14, and a channel(s) 18 defined in the polymeric substrate 14. The channel(s) 18 are configured to transfer a heat flow 20 away from the heat source 12 via a channel coolant flow 22 moving through the channel(s) 18. The polymeric substrate 14 of the present disclosure may be configured to distribute heat 20, enclose, and protect at least a portion 16 of the heat source 12. As one option, in the channel(s) 18, 24 defined in the polymeric substrate 14 may be in fluid communication with heat source 12. In another optional enhancement to this, the channel(s) 18, 24 which is/are in fluid communication with the heat source 12 may further define an increased cross-section 26 in the region 28 where the channel(s) 18, 24 intersects with the heat source 12. The polymeric substrate 14 may be formed from a rigid polymeric material when the polymeric substrate 14 completely encloses and protects the heat source 12. In this embodiment, the vascular polymeric assembly 10 may further include an internal support structure 58 configured to support the heat source 12. The internal support structure 58 may be enclosed and protected with the heat source 12 within the polymeric substrate 14.

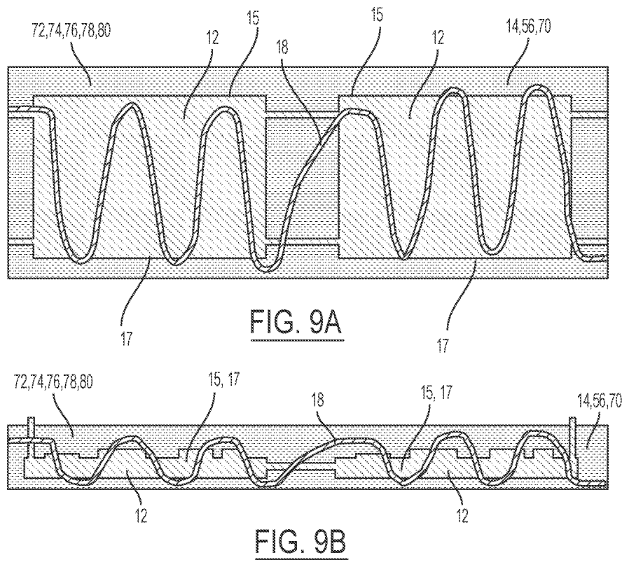

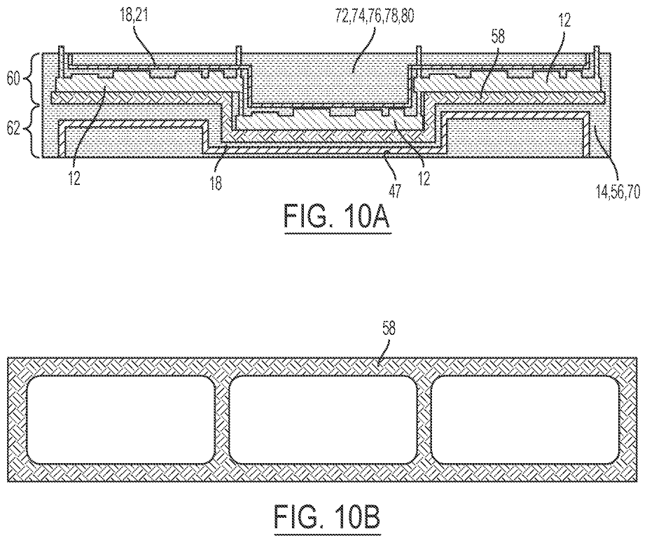

In this first embodiment, it is understood that the channel(s) 18, defined in the polymeric substrate 14, may be provided in both an upper region 60 and a lower region 62 of the polymeric substrate 14. As yet another option shown in FIGS. 4A and 4B, an upper heat spreader 64 may be disposed adjacent to the channel(s) 18, 21 defined in an upper region 60 of the polymeric substrate 14 while a lower heat spreader 68 may also be disposed adjacent to channel(s) 18, 19 defined in a lower region 62 of the polymeric substrate 14. With reference to FIG. 6B, sacrificial material 110 may be mechanically affixed to the heat spreader 64, 66 before heat source 12, heat spreader 64, 66, and sacrificial material is put into the mold. Nonetheless, with respect to this first embodiment (regardless of whether any heat spreaders 64, 68 are implemented within the substrate 14), the channel(s) 18 defined in the polymeric substrate 14 may also or alternatively be defined adjacent to at least one of a first side 15 and/or second side 17 of heat source 12 enclosed in a polymeric substrate as shown in FIGS. 9A-9B.

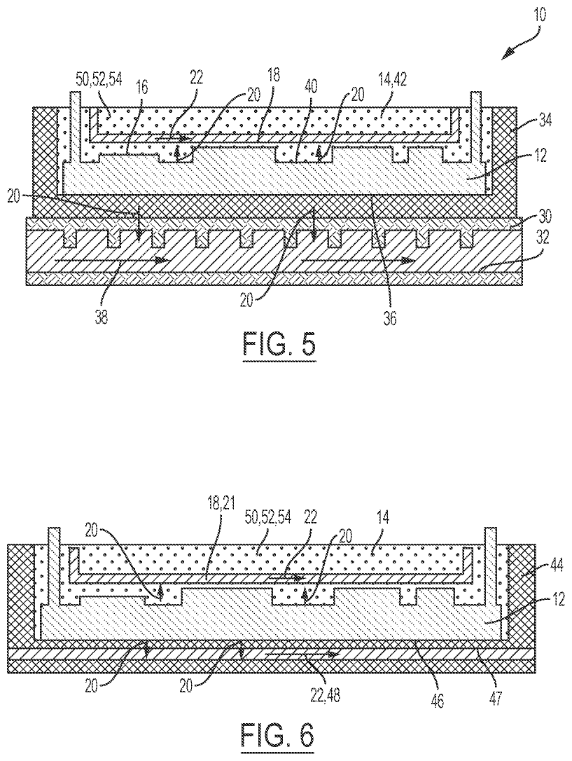

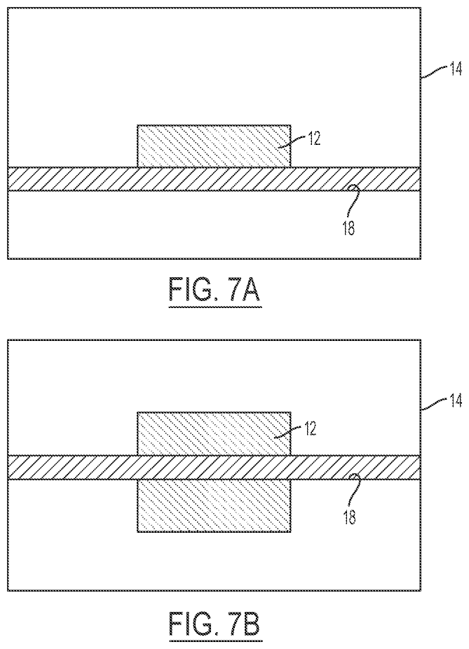

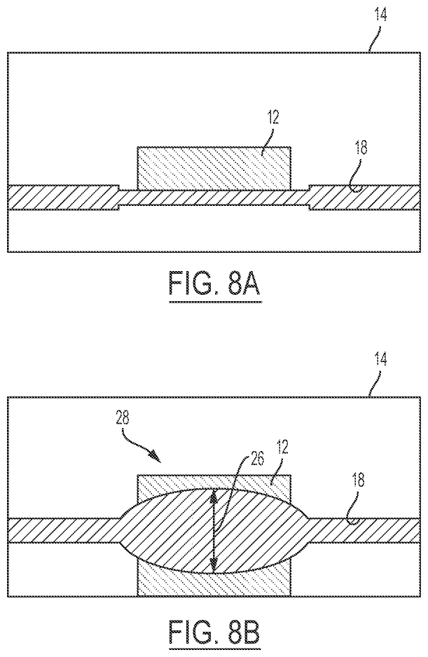

In a second embodiment shown in FIG. 5, the vascular polymeric assembly 10 may include a heat source 12, a polymeric substrate 14, and a channel(s) 18 defined in the polymeric substrate 14 in addition to a plate 30 and a structural (non-polymeric) case which is disposed on the plate 30. The plate 30 may be made from a variety of materials, such as but not limited to, metal, a ceramic based material, an injection molded polymer or a cast polymer (which may or may not be a highly filled thermoplastic). The structural (non-polymeric) case is configured to and supports the heat source 12 and polymeric substrate 14. The plate 30 may further define a plate coolant channel 32. The plate coolant channel 32, the plate 30 and structural case 34 are configured to distribute heat 20 away from a lower side 36 of the heat source 12 via a “plate coolant flow” 38 which moves through the plate coolant channel 32, while the channel(s) 18 in the polymeric substrate 14 are configured to transfer heat 20 away from an upper side 40 of the heat source 12 via a channel coolant flow 22 which moves through the channel(s) 18. It is understood that the plate coolant flow 38 is defined as the coolant fluid which flows through plate 30. As one option shown in FIGS. 7A-7B and 8A-8B, the channel(s) 18, 24 defined in the polymeric substrate 14 may be in fluid communication with heat source 12. As yet another optional enhancement to this, the channel(s) 18, 24 (which is/are in fluid communication with the heat source 12) may further define an increased cross-section 26 in the region where the channel(s) 18 intersects with the heat source 12 as shown in FIGS. 8A-8B.

In the embodiment shown in FIG. 5 which implements a plate 30 and a structural case 34, the polymeric substrate 14 may be formed by a flexible polymer 42. The flexible polymer 42 is less rigid relative to the structural case 34. The flexible polymer 42 defines a service temperature which is well above a glass transition temperature. The flexible polymer 42 material used in the polymeric substrate 14 may, but not necessarily, be one of a rubber 50, a silicone 52, or an elastomer 52.

In a third embodiment of the present disclosure shown in FIG. 6, a structural polymeric case 44 may be used instead of a structural case 34 and the plate 30 (see FIG. 5). In this third embodiment, the vascular polymeric assembly 10 includes a heat source 12, a polymeric substrate 14, and a channel(s) 18 defined in the polymeric substrate 14 and a structural polymeric case 44. The structural polymeric case 44 similarly supports the heat source 12 and the polymeric substrate 14 as previously described. However, the structural polymeric case 44 obviates the need for a plate 30 having a plate coolant channel 32 given that the structural polymeric case 44 also defines a lower coolant channel(s) 47 which is configured to transfer a heat flow 20 away from a lower side 36 of the heat source 12 via a lower coolant flow 48, 22 which travels through the lower coolant channel(s) 47. The coolant channel(s) 18 defined in the upper region 60 may be alternatively referred to as an upper coolant channel(s) 21. The structural polymeric case 44 may be formed from a structural polymer 56 which is in a glassy state such that the structural polymer's service temperature is below a glass transition temperature. The structural polymer 56 material used for the structural polymeric case 44 may, but not necessarily, be one of an epoxy 72, a polyurethane 74, a polyimide 76, a polypropylene 78, or a nylon 80. It is also understood that the polymeric substrate 14 of FIG. 6 is formed from a flexible polymer 42 which makes the polymeric substrate 14 less rigid relative to the structural case 34. The flexible polymer is less rigid compared to the rigidity of the structural case 34.

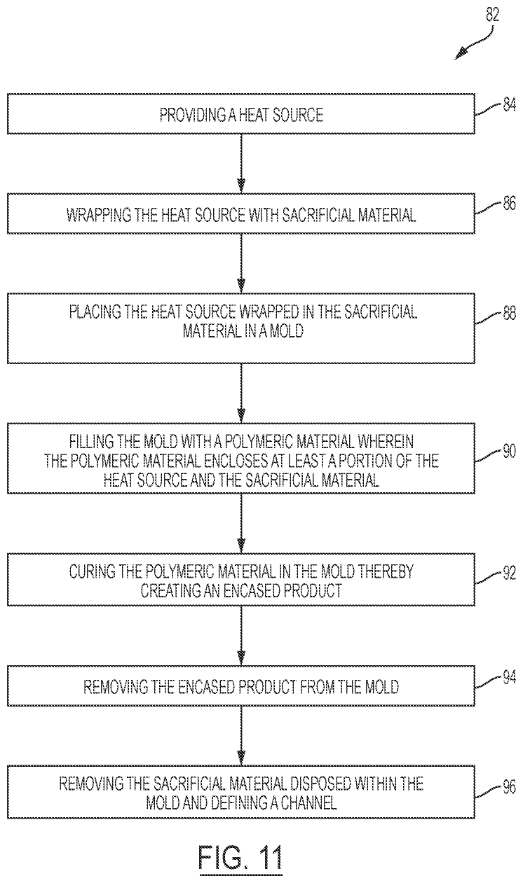

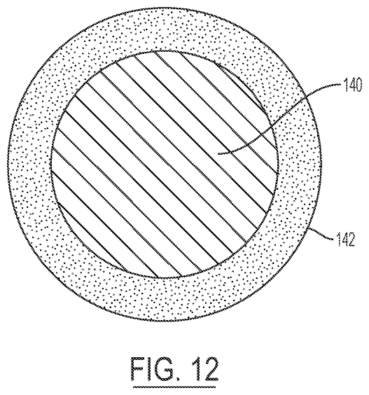

Referring now to FIG. 11, the present disclosure also provides a method 82 for manufacturing a vascular polymeric assembly 10 which may include the steps of: (1) providing a heat source 12; step 84 (2) wrapping the heat source 12 with a sacrificial material 110; step 86 (3) placing the heat source 12 wrapped in the sacrificial material 110 in a mold; step 88 (4) filling the mold with a polymeric material wherein the polymeric material encloses at least a portion 16 of the heat source 12 and the sacrificial material 110; step 90 (5) curing the polymeric material in the mold thereby creating an encased product; step 92 (6) removing the encased product from the mold; step 94 and (7) removing the sacrificial material 110 disposed within the mold and defining a channel(s) 18. Step 96 The method 82 may optionally further include one or more of the following steps: the step of providing a channel coolant flow 22 through the channel(s) 18; step 98 and the step of disposing the heat source 12 in a structural case 34 and placing the heat source 12 and the structural case 34 together in the mold. step 100. The heat source 12 implemented in the aforementioned manufacturing method may, but not necessarily be, an electronics module 102, a stator 104, or a portion of a stator 106.

It is understood that the step of filling the mold with the polymeric material may, but not necessarily be performed by a dual shot injection molding process wherein a structural polymer 56 is provided in at least a lower region 62 of the mold below the heat source 12 and a flexible polymer 42 is provided in at least an upper region 60 of the mold above the heat source 12. Alternatively, the step of filling the mold with the polymeric material may, but not necessarily, be performed by a single injection molding process wherein the mold is filled with one structural polymer 56.

With respect to the step of wrapping the heat source 12 in the sacrificial material 110, it is understood that this step may be performed in a variety of ways. One example method of wrapping the heat source 12 involves wrapping only an upper side 40 of the heat source 12 with the sacrificial material 110. Another, non-limiting example method of wrapping the heat source 12 involves wrapping the heat source 12 in a sacrificial material 110 includes wherein both an upper side 40 and a lower side 36 of the heat source 12 are wrapped. With respect to the step of removing the sacrificial material 110, it is understood that the sacrificial material 110 may be removed in various ways. One example way is disclosed in pending patent application Ser. No. 15/829,051, which is incorporated herein by reference.

In one example, the sacrificial material 110 may be molded directly to the substrate such that the sacrificial material 110 is at least partially disposed inside the substrate. For instance, after molding, a majority of the sacrificial material 110 may be entirely disposed inside the substrate to facilitate the formation of thru-holes. However, at least part of the sacrificial material 110 should be disposed outside of the substrate to allow it to be ignited as discussed below.

Moreover, under this method step which removes the sacrificial material 110, the sacrificial material 110 may, but not necessarily, include a combustible core 140 and a protective shell 142 surrounding the combustible core. The combustible core allows for rapid deflagration but not detonation. The heat generated during deflagration is dissipated rapidly enough to prevent damage to the substrate. After deflagration, the combustible core generates easy-to-remove byproducts, such as fine powdered and large gaseous components. It is contemplated that the combustible core may be self-oxidizing to burn in a small diameter along long channels. The combustible core is also resistant to molding pressures. Further, the combustible core is shelf stable and stable during manufacturing (i.e., the flash point is greater than the manufacturing or processing temperature). The term “flash point” means the lowest temperature at which vapors of a combustible material will ignite, when given an ignition source. The sacrificial material 110 may be molded directly to the substrate at a processing temperature that is less than the flash point of the combustible material to avoid deflagration during the manufacturing process. The term “processing temperature” means a temperature required to perform a manufacturing operation, such as molding or casting. For example, the processing temperature may be the melting temperature of the material forming the substrate (i.e., the melting temperature of the polymeric resin forming the substrate). The combustible core is wholly or partly made of a combustible material.

To achieve the desired properties mentioned above, the combustible material may be black powder (i.e., a mixture of sulfur, charcoal, and potassium nitrate). To achieve the desired properties mentioned above, the combustible material may alternatively or additionally be pentaerythritol tetranitrate, combustible metals, combustible oxides, thermites, nitrocellulose, pyrocellulose, flash powders, and/or smokeless powder. Non-combustible materials could be added to the combustible core to tune speed and heat generation. To tune speed and heat generation, suitable non-combustible materials for the combustible core include, but are not limited to, glass beads, glass bubbles, and/or polymer particles.

The protective shell is made of a protective material, which may be non-soluble material in combustible resin (e.g., epoxy, polyurethane, polyester, among others) in order to be shelf stable and stable during manufacturing. Also, this protective material is impermeable to resin and moisture. The protective material has sufficient structural stability to be integrated into a fiber textiling and preforming process. The protective material has sufficient strength and flexibility to survive the fiber preform process. To achieve the desirable properties mentioned above, the protective material may include, for example, braided fibrous material, such as glass fiber, aramid fiber, carbon fiber, and/or natural fiber, infused with an infusion material such as a polymer or wax, oil, a combination thereof or similar material. To achieve the desirable properties mentioned above, the infused polymer may be, for example, polyimide, polytetrafluoroethylene (PTFE), high-density polyethylene (HDPE), polyphenylene sulfide (PPS), polyphthalamide (PPA), polyamides (PA), polypropylene, nitrocellulose, phenolic, polyester, epoxy, polylactic acid, bismaleimides, silicone, acrylonitrile butadiene styrene, polyethylene, polycarbonate, elastomer, polyurethane, polyvinylidene chloride (PVDC), polyvinyl chloride (PVC), polystyrene (PS) a combination thereof, or any other suitable plastic. Suitable elastomers include, but are not limited to, natural polyisoprene, synthetic polyisoprene, polybutadiene (BR), chloroprene rubber 50 (CR), butyl rubber, styrene-butadiene rubber, nitrile rubber, ethylene propylene rubber, epichlorohydrin rubber (ECO), polyacrylic rubber, fluorosilicone rubber, perfluoroelastomers, polyether block amides, chlorosulfonated polyethylene, ethylene-vinyl acetate, shellac resin, nitrocellulose lacquer, epoxy resin, alkyd, polyurethane, etc.

In one example method step to remove the sacrificial material 110, the sacrificial material 110 may ignited such that a flame may be placed in direct contact with the sacrificial material 110 to cause an ignition I. The ignition I causes deflagration of the sacrificial material 110. Deflagration converts the solid sacrificial material 110 into gaseous and fine powder byproducts. As a consequence, channel is formed in the substrate. The sacrificial material 110 may be cylindrical in order to form the channel with a cylindrical shape. The sacrificial material 110 may alternatively have other shapes, such as triangular, elliptical, square, etc. Further, before ignition I, the sacrificial material 110 may extend through the entire length of the substrate such that, after deflagration, the channel may extend through the entire length of the substrate.

After deflagration, the channel may be cleaned to remove byproducts of the deflagration of the sacrificial material 110. To do so, a liquid W, such as water, may be introduced into the channel of the polymeric substrate 14 to remove byproducts of the deflagration of the sacrificial material 110. A gas, such as air, may alternatively or additionally may be shot into the channel to remove byproducts of the deflagration of the sacrificial material 110. It is understood that this is only one of many ways upon which the sacrificial material 110 is removed from the polymeric substrate 14. Additional examples may be found in patent application Ser. No. 15/829,051 which is incorporated herein by reference.

The present disclosure's method of manufacturing a vascular polymeric assembly 10 may be implemented with a variety of powered devices such as, but not limited to, an electronics board, a motor component (such as but not limited to a stator or rotor), a portion of a motor component, an engine control unit, a portion of an internal combustion engine, or a touch screen on an instrument.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A vascular polymeric assembly comprising:
a heat source;
a polymeric substrate configured to enclose and protect at least a portion of the heat source; and
a channel defined in the polymeric substrate configured to transfer a heat flow away from the heat source via a channel coolant flow.

2. The vascular polymeric assembly as defined in claim 1 wherein the channel is in fluid communication with heat source.

3. The vascular polymeric assembly as defined in claim 2 wherein the channel is in fluid communication with the heat source and defines an increased cross-section in a region where the channel intersects with the heat source.

4. The vascular polymeric assembly as defined in claim 1 further comprising:
a plate defining a plate coolant channel; and
a structural case disposed on the plate;
wherein the structural case is configured to support the polymeric substrate and the heat source.

5. The vascular polymeric assembly as defined in claim 4 wherein the plate and the coolant channel are configured to transfer heat away from a lower side of the heat source via a plate coolant flow while the channel in the polymeric substrate are configured to transfer heat away from an upper side of the heat source via the channel coolant flow.

6. The vascular polymeric assembly as defined in claim 5 wherein the polymeric substrate is a flexible polymer such that the polymeric substrate is less rigid relative to the structural case.

7. The vascular polymeric assembly as defined in claim 1 further comprising:
a structural polymeric case supporting the heat source and the polymeric substrate, the structural polymeric case defining a lower coolant channel configured to transfer heat away from a lower side of the heat source via a lower coolant flow.

8. The vascular polymeric assembly as defined in claim 1 wherein the polymeric substrate is configured to completely enclose and protect the heat source.

9. The vascular polymeric assembly as defined in claim 6 wherein the flexible polymer is configured to operate above a glass transition temperature.

10. The vascular polymeric assembly as defined in claim 6 wherein the polymeric substrate is one of a rubber, a silicone, and an elastomer.

11. The vascular polymeric assembly as defined in claim 8 wherein the polymeric substrate is a structural polymer.

12. The vascular polymeric assembly as defined in claim 8 further comprising an internal support structure configured to support the heat source, the internal support structure being enclosed and protected with the heat source within the polymeric substrate.

13. The vascular polymeric assembly as defined in claim 8 wherein an upper coolant channel is defined in the polymeric substrate in an upper region and a lower coolant channel is defined in a lower region of the polymeric substrate.

14. The vascular polymeric assembly as defined in claim 13 further comprising:
an upper heat spreader disposed adjacent to the upper coolant channel defined in the upper region of the polymeric substrate.

15. The vascular polymeric assembly as defined in claim 14 further comprising a lower heat spreader disposed adjacent to the lower coolant channel defined in the lower region of the polymeric substrate.

16. The vascular polymeric assembly as defined in claim 11 wherein the structural polymer is a polymer which is configured to operate below a glass transition temperature.

17. The vascular polymeric assembly as defined in claim 13 wherein the polymeric substrate is a structural polymer in a glassy state such that the polymeric substrate's service temperature is below a glass transition temperature.

18. The vascular polymeric assembly as defined in claim 17 wherein the structural polymer is one of an epoxy, a polyurethane, a polyimide, a polypropylene, a nylon, a bismaleimide, a benzoxazine, a phenolic, a polyester, a polyvinylchloride, a melamine, a cyanate ester, a silicone, a vinyl ester, a thermoplastic olefin, a polycarbonate, a polyether sulfone, a polystyrene, or a polytetrafluoroethylene.

19. A method for manufacturing a vascular polymeric assembly, the method comprising the steps of:
providing a heat source;
wrapping the heat source with a sacrificial material;
placing the heat source wrapped in the sacrificial material in a mold;
filling the mold with a polymeric material wherein the polymeric material encloses at least a portion of the heat source and the sacrificial material;
curing the polymeric material in the mold thereby creating an encased product;
removing the encased product from the mold; and
removing the sacrificial material disposed within the mold and defining a channel.

20. The method as defined in claim 19 further comprising the step of providing a coolant flow through the channel.

21. The method as defined in claim 19 further comprising the step of disposing the heat source in a structural case and placing the heat source and the structural case together in the mold.

22. The method as defined in claim 19 wherein the heat source is an electronics module.

23. The method as defined in claim 19 wherein the step of filling the mold with the polymeric material is a dual shot injection molding process wherein a structural polymer is provided in at least a lower region of the mold below the heat source and a flexible polymer is provided in at least an upper region of the mold above the heat source.

24. The method as defined in claim 19 wherein the polymeric material which fills the mold is a structural polymer.

25. The method as defined in claim 19 wherein the step of filling the mold with the polymeric material is a casting process wherein a structural polymer is provided in at least a lower region of the mold below the heat source and a flexible polymer is provided in at least an upper region of the mold above the heat source.

26. The method as defined in claim 21 wherein the step of wrapping the heat source in the sacrificial material is limited to wrapping one of an upper side of the heat source or a lower side of the heat source with the sacrificial material.

27. The method as defined in claim 23 wherein the step of wrapping the heat source in the sacrificial material includes wrapping an upper side and a lower side of the heat source.

28. The method as defined in claim 24 wherein the step of wrapping the heat source in the sacrificial material includes wrapping an upper side and a lower side of the heat source with the sacrificial material.
